(19) United States
(12) Patent Application Publication
(10) Pub. No.: US 2005/0206765 A1
(43) Pub. Date: Sep. 22, 2005

(54) Solid-state image pickup device

(75) Inventor: Yoshimitsu Nakashima, Yamatokooriyama-shi (JP)

Correspondence Address: EDWARDS & ANGELL, LLP, P.O. BOX 55874, BOSTON, MA, 02205, US

(73) Assignee: Sharp Kabushiki Kaisha

(21) Appl. No.: 11/068,682

(22) Filed: Feb. 28, 2005

(30) Foreign Application Priority Data
Mar. 1, 2004 (JP) P2004-056146

(51) Int. Cl. H04N 5/335

(52) U.S. Cl. 348/308

(57) ABSTRACT

The solid-state image pickup device has a plurality of light-receiving portions, vertical transfer channels and sets of vertical transfer electrodes on a surface of a semiconductor substrate. The light-receiving portions in each column are separated apart by pixel isolation regions. In each vertical transfer channel, the width of a second portion located beside a pixel isolation region is wider than the width of a first portion located beside a light-receiving portion.

This nonprovisional application claims priority under 35 U.S.C. §119(a) on Patent Application No. 2004-056146 filed in Japan on Mar. 1, 2004, the entire contents of which are hereby incorporated by reference.

### BACKGROUND OF THE INVENTION

The present invention relates to solid-state image pickup devices and, in particular, to a CCD (Charge Coupled Device) type solid-state image pickup device. The solid-state image pickup device of this kind is employed as an image sensor to be mounted on a portable telephone, a digital still camera, a digital video camera or the like.

As a CCD type solid-state image pickup device, a two-dimensional image sensor as shown in, for example, FIG. 9 is known (refer to, for example, JP 2002-118250 A). The two-dimensional image sensor has, in a rectangular area 101 set on a semiconductor substrate, a plurality of light-receiving portions (photodiodes) 104 arranged in a matrix shape and a plurality of vertical transfer channels 105 extending in the vertical direction (vertical direction of FIG. 9) along the columns of the light-receiving portions 104. The light-receiving portions 104 are arranged at a prescribed pitch PV in the vertical direction. The vertical transfer channels 105 are arranged together with the light-receiving portions 104 at a prescribed pitch PH in the horizontal direction (transverse direction of FIG. 9). One end (the lower end in FIG. 9) of each of the vertical transfer channels 105 is connected to a horizontal transfer channel 102 extending in the horizontal direction. Reference numeral 103 denotes an amplifier. As shown in FIG. 10, a set of four-phase vertical transfer electrodes 108, 109, 110 and 111 constructed of polysilicon doped with impurity is provided on the vertical transfer channels 105. Although only one set of vertical transfer electrodes is shown in FIG. 10 for the sake of simplicity, numbers of sets identical to the set are actually provided in the vertical direction at the same pitch as that PV of the light-receiving portions 104. The vertical transfer electrodes 108, 109, 110 and 111 in each set partially overlap one another and sequentially face portions of the vertical transfer channels 105 in the vertical direction to control the potentials of the corresponding portions of the vertical transfer channels 105. Moreover, a transfer gate region 106 for interrupting or passing the signal charge is provided between the light-receiving portion 104 and the vertical transfer channel 105. It is noted that the vertical transfer electrode 108 concurrently serves as a transfer gate electrode for reading the signal charge from the light-receiving portion 104 to the vertical transfer channel 105. Further, the light-receiving portions 104 arranged in the vertical direction are separated apart by pixel isolation regions 107, so that the signal charges are not mixed with each other.

In operation, the light-receiving portion 104 converts incident light into signal charge and stores the charge. Four-phase transfer signals (clock pulses) are applied to the set of the vertical transfer electrodes 108, 109, 110 and 111 by an external circuit (not shown). As a result, the signal charge generated by the light-receiving portion 104 is read to the vertical transfer channel 105 via the associated transfer gate region 106 located adjacent to the light-receiving portion 104 and transferred in the vertical direction through the vertical transfer channel 105 toward the horizontal transfer channel 102. The signal charge transferred to the horizontal transfer channel 102 is further transferred in the horizontal direction through the horizontal transfer channel 102 toward the amplifier 103, and then amplified by the amplifier 103 and outputted.

In the solid-state image pickup devices of this kind, a size reduction with cell size reduction and an increase in the number of pixels are being earnestly promoted. Therefore, the vertical transfer channels 105 are also reduced in width, and it has become difficult to secure an adequate amount of charge in the vertical transfer channel 105.

If the area of the light-receiving portion 104 is reduced in order to expand the width of the vertical transfer channel 105 with the cell size kept constant, the storage capacitance of the light-receiving portion 104 is reduced, disadvantageously causing a reduction in sensitivity and a reduction in the dynamic range.

Moreover, if the transfer gate region 106 is narrowed in order to expand the width of the vertical transfer channel 105 from, for example, W0 shown in FIG. 11A to Wx shown in FIG. 11B, the potential of the transfer gate region 106 is deepened from φ0 to ψx. Therefore, a potential barrier between the light-receiving portion 104 and the vertical transfer channel 105 is lowered, disadvantageously reducing the storage capacitance of the light-receiving portion 104. The trouble occurs when the vertical transfer channel (vertical transfer register) is gradually expanded in the transfer direction as in, for example, JP 63-15459 A.

### SUMMARY OF THE INVENTION

An object of the present invention is to provide a solid-state image pickup device capable of increasing the throughput, or the amount of charge that the vertical transfer channel can transfer, without narrowing the light-receiving portion or the transfer gate region.

In order to accomplish the above object, a solid-state image pickup device according to the present invention includes:
a plurality of light-receiving portions which are arranged in a matrix form at a surface of a semiconductor substrate and convert incident light into signal charge;
vertical transfer channels each extending in one direction along respective columns of the light-receiving portions on the surface of the semiconductor substrate; and
a set of vertical transfer electrodes which are arranged on each vertical transfer channel and control potentials of corresponding portions of the vertical transfer channel so as to transfer the signal charge through the vertical transfer channel, wherein
the light-receiving portions in each column are separated apart by pixel isolation regions; and
each vertical transfer channel comprises at least a first portion and a second portion, the second portion has a width greater than a width of the first portion, the first portion is aligned with a light-receiving portion in a direction of row, and the second portion is aligned with a pixel isolation region in the direction of row.

Herein, portions of the vertical transfer channel “corresponding to” the respective vertical transfer electrode means that the portions of the vertical transfer channel (semiconductor substrate surface) face the respective vertical transfer electrode, from the viewpoint of controlling potentials of the vertical transfer channel.

Moreover, the “width” of the vertical transfer channel (including the first portion and the second portion) indicates a width in a direction perpendicular to the direction in which the channel extends within the semiconductor substrate surface.

In the solid-state image pickup device of the present invention, in operation, the light-receiving portion converts incident light into a signal charge and stores the charge. The signal charge is transferred to the vertical transfer channel through, for example, a transfer gate region (region provided between the light-receiving portion and the vertical transfer channel to interrupt or pass the signal charge). Then, a prescribed transfer signal like, for example, multi-phase clock pulses is applied to the set of vertical transfer electrodes provided on the vertical transfer channel. By this operation, potentials of the portions corresponding to each vertical transfer electrode of the vertical transfer channel are controlled. Consequently, the signal charge is transferred through the vertical transfer channel.

In the two-dimensional image sensor of the invention, the width of the second portion located beside the pixel isolation region of the vertical transfer channel is wider than the width of the first portion of the vertical transfer channel located beside the light-receiving portion. When the width of the vertical transfer channel is at least partially widened like this, the width of the vertical transfer channel is virtually widened, and the amount of charge that the vertical transfer channel can transfer is increased. In addition, the second portion of the increased width of the vertical transfer channel is a portion located beside the pixel isolation region, and this therefore exerts no influence on the areas of the light-receiving portion and the transfer gate region. Therefore, the amount of charge that the vertical transfer channel can transfer is increased without narrowing the light-receiving portion or the transfer gate region.

In one embodiment, the vertical transfer channels each have a width varied continuously or stepwise between at least the second portion and the first portion located adjacent to the second portion on a downstream side in a transfer direction, and a boundary between adjoining two vertical transfer electrodes on a vertical transfer channel exists on a transition region of the vertical transfer channel where the width of the vertical transfer channel is varied continuously or stepwise between the second portion and the first portion located adjacent to the second portion on the downstream side in the transfer direction.

Herein, the term “boundary” between two adjoining vertical transfer electrodes means a “boundary” that faces the vertical transfer channel (semiconductor substrate surface) from the viewpoint of controlling the potential of the vertical transfer channel. Therefore, when the two vertical transfer electrodes overlap each other, the “boundary” corresponds to an end portion of the vertical transfer electrode located on the lower side.

As already described, when the width of the second portion of the vertical transfer channel is expanded, a potential barrier against the signal charge may be generated between the second portion of the vertical transfer channel and the first portion adjoining the second portion due to the widened bottom of the potential. In the solid-state image pickup device of the embodiment, the boundary between the two mutually adjoining vertical transfer electrodes on the vertical transfer channel exists on the transition region where the width of the vertical transfer channel is varied continuously or stepwise between the second portion and the first portion located adjacent to the second portion on the downstream side in the transfer direction. Therefore, if, of mutually adjoining two vertical transfer electrodes, one vertical transfer electrode located on the downstream side in the transfer direction has a higher applied voltage than the other located on the upstream side in the transfer direction when signal charge passes through the transition region varied continuously or in steps, the possible potential barrier is canceled. Therefore, the occurrence of defective vertical transfer is suppressed, and the signal charge is smoothly transferred.

In one embodiment, the width of the second portion of the vertical transfer channel is expanded only on one side with respect to the first portion.

The term “one side” herein means one of two lateral sides of the vertical transfer channel, within the semiconductor substrate surface.

In the present embodiment, the amount of charge that the vertical transfer channel can transfer can be increased without narrowing the light-receiving portion or the transfer gate region, similarly to the case where the width of the second portion of the vertical transfer channel is expanded on both sides with respect to the first portion.

In one embodiment, the second portion faces one vertical transfer electrode, the first portion faces a plurality of vertical transfer electrodes, and the second portion has a length shorter than lengths of portions of the first portion that correspond to each of the plurality of vertical transfer electrode.

The term “length” of the first portion and of the second portion herein means a length in a direction in which the vertical transfer channel extends, i.e., a length along the transfer direction.

In the present embodiment, because the length of the second portion is shorter than the lengths of the portions corresponding to each of the plurality of vertical transfer electrode in the first portion, an increase in the occupation area of the second portion due to its increased width is suppressed. Conversely, the lengths of the portions corresponding to each of the vertical transfer electrode of the first portion can be increased by that much. By virtue of a resulting increased length of a transfer gate electrode located in an area of the first portion corresponding to the transfer gate region, a read voltage at which the signal charge stored in a light-receiving portion is read from the light-receiving portion to the vertical transfer channel can be reduced. As a result, the storage capacitance of the light-receiving portion can be increased. This is beneficial in securing a required amount of signal charge when the cell size is shrunk in accordance with the reduction in size of the solid-state image pickup device and/or the increase in number of pixels of the solid-state image pickup device.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a diagram showing a plan layout of a progressive scan type two-dimensional image sensor according to one embodiment of the solid-state image pickup device of the present invention;

FIG. 2A is a diagram showing a vertical transfer channel and FIG. 2B is a graph showing a potential barrier Δφ generated between a second portion where the width of the vertical transfer channel is wide and a first portion located adjacent to the second portion;

FIG. 3 is a view showing vertical transfer electrodes of the two-dimensional image sensor;

FIG. 4 is a sectional view taken along line A-A′ of FIG. 3;

FIG. 5 is a timing chart showing four-phase clock pulses φV1, φV2, φV3 and φV4 applied to the vertical transfer electrodes of the two-dimensional image sensor;

FIGS. 6A and 6B are diagrams showing the potential distribution of the vertical transfer channel at timings t1 and t2, respectively, in FIG. 5;

FIG. 7 is a diagram showing a plan layout of a modification example of the two-dimensional image sensor;

FIG. 8 is a diagram showing a vertical transfer channel of the modification example of the two-dimensional image sensor;

FIG. 9 is a diagram showing a schematic plan layout of a two-dimensional image sensor of background art;

FIG. 10 is a view showing vertical transfer electrodes of the two-dimensional image sensor of background art; and

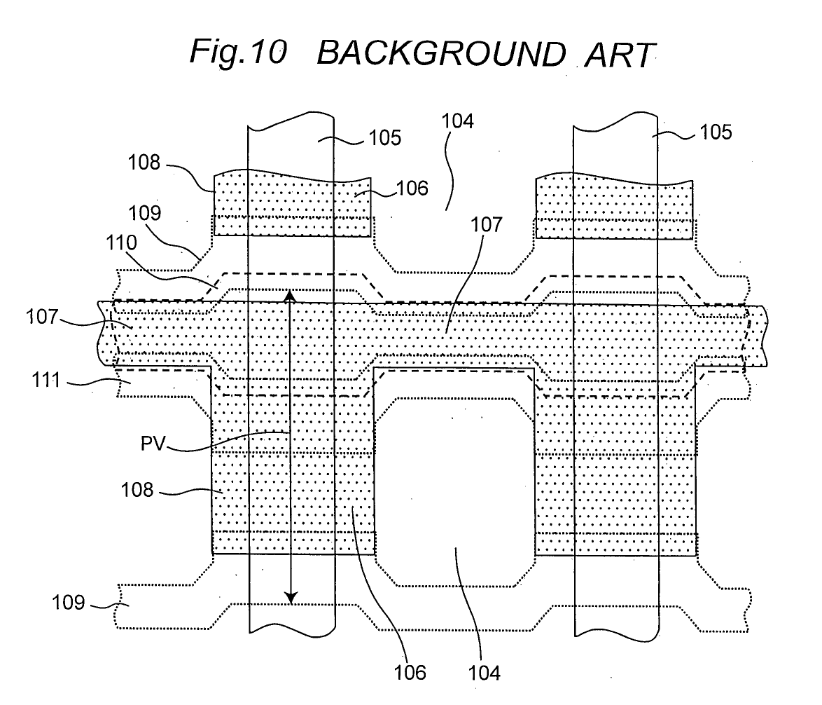

FIGS. 11A and 11B are graphs for explaining a problem when the transfer gate region is narrowed

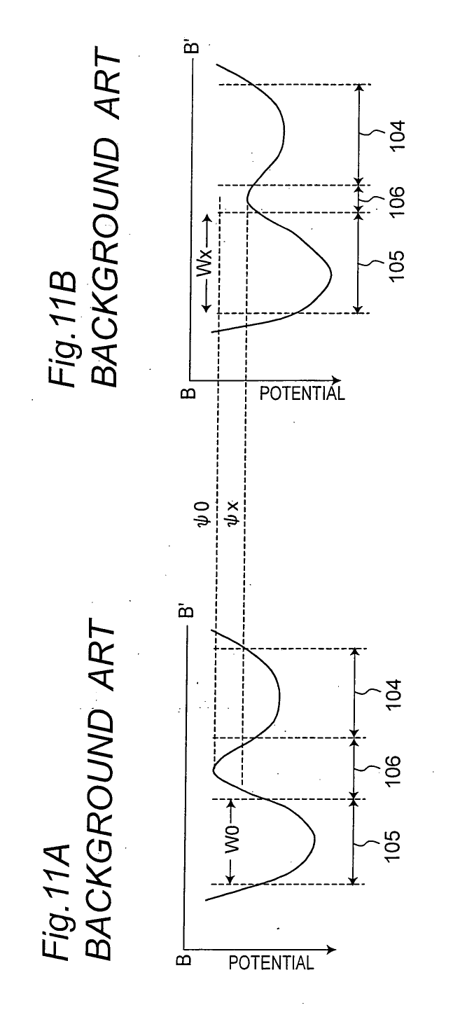

### DETAILED DESCRIPTION OF THE INVENTION

The solid-state image pickup device of the present invention will be described in detail below based on the shown embodiments.

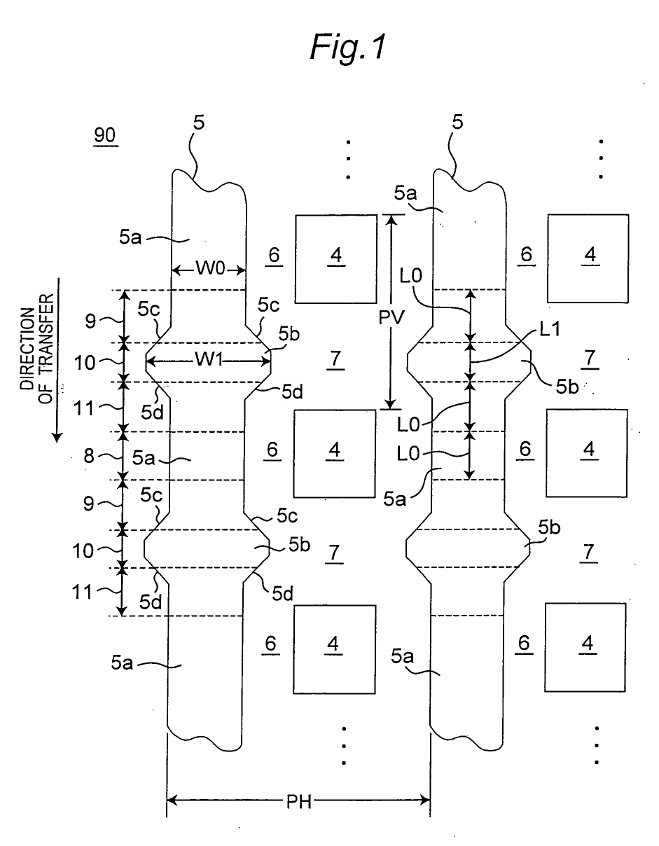

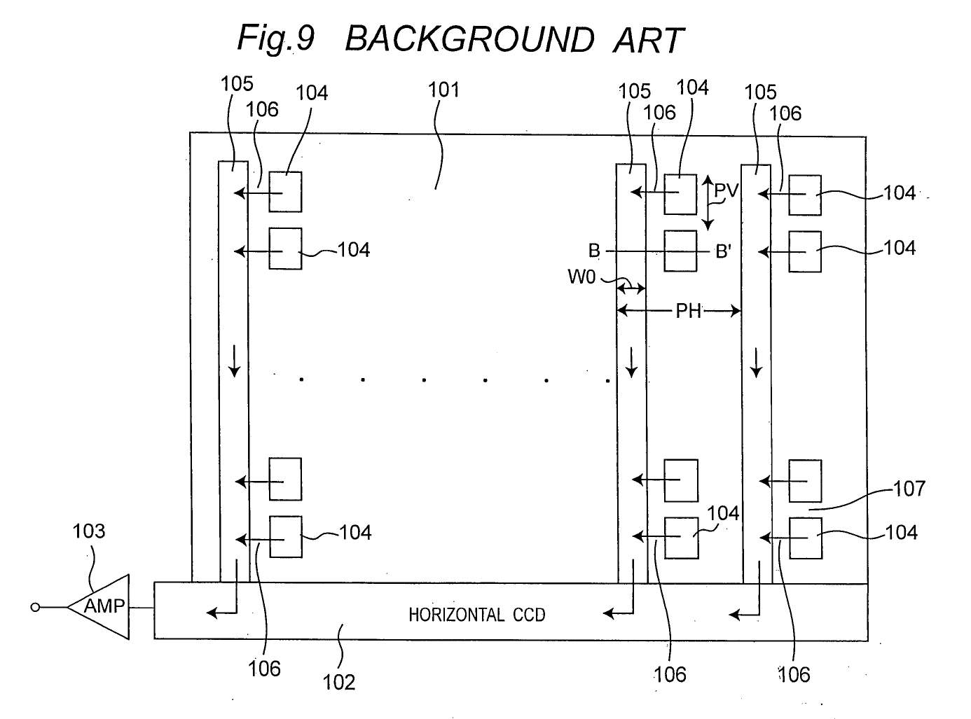

FIG. 1 shows a plan layout of a progressive scan type two-dimensional image sensor according to one embodiment of the solid-state image pickup device of the present invention. The two-dimensional image sensor has, in a rectangular area 90 set at a surface of a semiconductor substrate surface, a plurality of light-receiving portions (photodiodes) 4 arranged in a matrix form and a plurality of vertical transfer channels 5 extending in the vertical direction (vertical direction of FIG. 1) along the columns of the light-receiving portions 4. The light-receiving portions 4 are arranged at a prescribed pitch PV in the vertical direction. The vertical transfer channels 5 are arranged together with the light-receiving portions 4 at a prescribed pitch PH in the horizontal direction (transverse direction of FIG. 1). One end (the lower end in FIG. 1) of each of the vertical transfer channels 5 is connected to a horizontal transfer channel extending in the horizontal direction, which channel is in turn connected to an amplifier, as in the image sensor of FIG. 9, although the horizontal transfer channel and the amplifier are not shown in FIG. 1.

A transfer gate region 6 for interrupting or passing the signal charge is provided between the light-receiving portion 4 and the vertical transfer channel 5. Further, the light-receiving portions 4 arranged in the vertical direction are separated apart by pixel isolation regions 7, so that the signal charges are not mixed with each other. That is, a region located between two light receiving portions adjacent in the column direction to electrically isolate these light-receiving portions serves as the pixel isolation region 7.

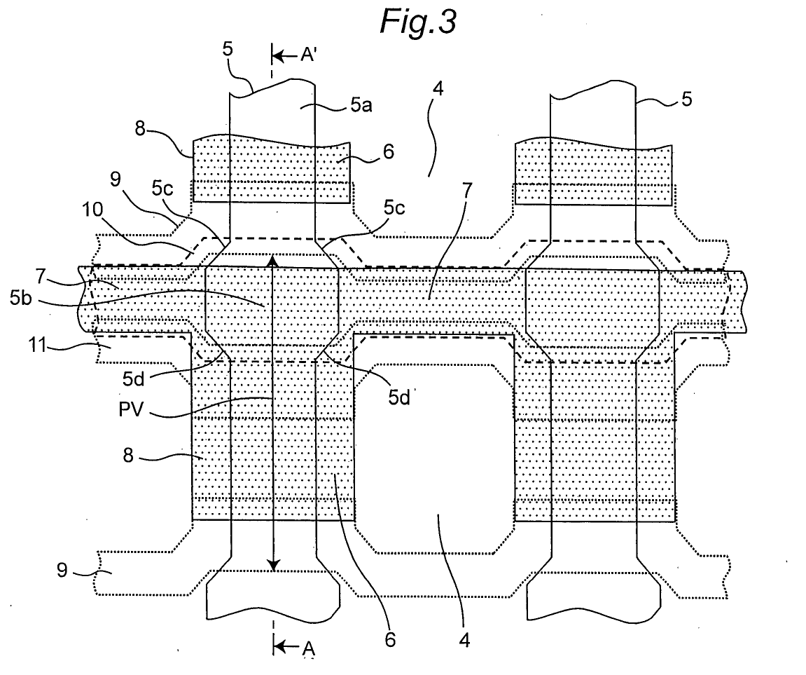

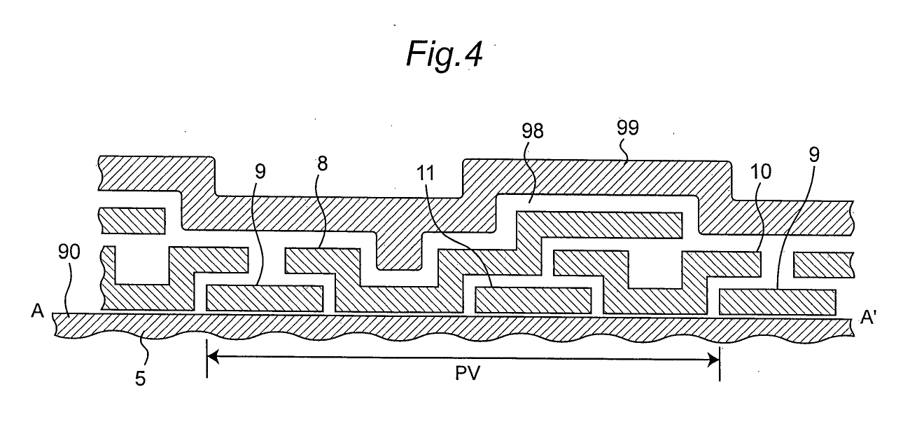

As shown in FIG. 3 in an enlarged manner, sets of four-phase vertical transfer electrodes 8, 9, 10 and 11 constructed of polysilicon doped with impurity are provided on the vertical transfer channels 5 FIG. 4 is a sectional view taken along line A-A′ in FIG. 3. Reference numeral 98 denotes an interlayer insulation film and reference numeral 99 denotes a light shielding film. Although only one set of vertical transfer electrodes is shown in FIGS. 3 and 4 for the sake of simplicity, numbers of sets of vertical transfer electrodes identical to the shown one are actually arranged in the vertical direction at the same pitch as that PV of the light-receiving portions 4. The vertical transfer electrodes 8, 9, 10 and 11 in each set partially overlap one another and sequentially face portions of the vertical transfer channels 5 in the vertical direction to control the potentials of the corresponding portions of the vertical transfer channels 5. It is noted that the vertical transfer electrode 8 concurrently serves as a transfer gate electrode for reading the signal charge from the associated light-receiving portion 4 to the vertical transfer-channel 5.

In FIG. 1, the dashed lines dividing the vertical transfer channels 5 show the boundaries of the portions of the vertical transfer channels 5 corresponding to the vertical transfer electrodes 8, 9, 10 and 11. The first portions; 5a of the vertical transfer channels 5 located beside the light-receiving portions 4 correspond to the vertical transfer electrodes 11, 8 and 9. The second portions 5b of the vertical transfer channels 5 located beside the pixel, isolation regions 7 correspond to the vertical transfer electrodes 10 only.

What is important with regard to the first portions 5a and the second portions 5b of the vertical transfer channel 5 is that the width W1 of the second portions 5b is wider than the width W0 of the first portions 5a, that the first portions 5a are aligned with the light-receiving portions 4 in the direction of row, and that the second portions 5b are aligned with the pixel isolation regions 7 in the direction of row. That is, the width W1 of the second portions 5b located beside the pixel isolation regions 7 is made wider than the width W0 of the first portions 5a located beside the light-receiving portions 4. The width of each vertical transfer channel 5 is varied continuously between the second portion 5b (portion corresponding to the vertical transfer electrode 10) and each of the first portions 5a and 5a (portions corresponding to the vertical transfer electrodes 9 and 11) adjoining the second portion 5b on the upstream side and the downstream side in the transfer direction. Reference numerals 5c and 5d denote (the outlines of) transition regions where the width of the vertical transfer channel 5 is continuously varied. The boundary between the vertical transfer electrodes 9 and 10 is located on the transition region 5c where the width of the vertical transfer channel is continuously varied, and the boundary between the vertical transfer electrodes 10 and 11 is located on the transition region 5d. It is noted that when two vertical transfer electrodes overlap each other, the “boundary” therebetween corresponds to an end of one of the vertical transfer electrodes which is located on the lower side.

Moreover, a length L1 along the transfer direction of the portion 5b of the vertical transfer channel 5 corresponding to the vertical transfer electrode 10 is made shorter than a length L0 along the transfer direction of the portions corresponding to each of the vertical transfer electrodes 8, 9 and 11.

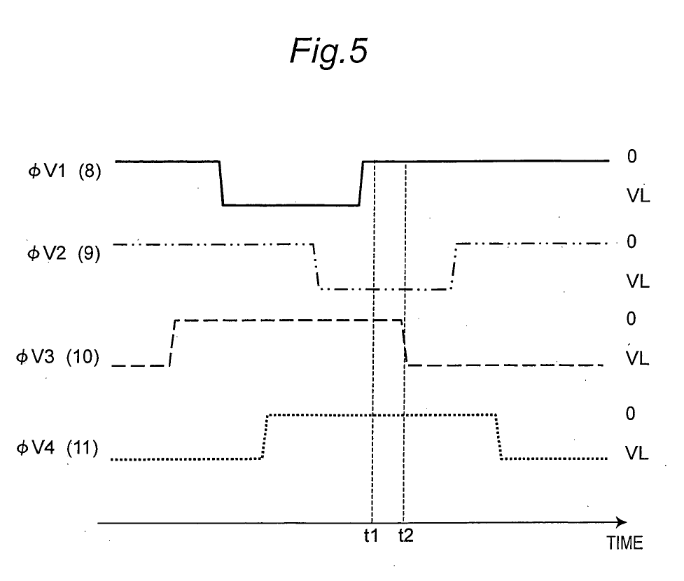

The two-dimensional image sensor operates basically similarly to the image sensor shown in FIG. 9. That is, in operation, the light-receiving portion 4 converts incident light into signal charge and stores the charge. Four-phase transfer signals φV1, φV2, φV3 and φV4 (clock pulses) as shown in FIG. 5 are applied to the set of the vertical transfer electrodes 8, 9, 10 and 11 by an external circuit (not shown) As a result, the signal charge generated by the light-receiving portion 4 is read to the vertical transfer channel 5 via the associated transfer gate region 6 located adjacent to the light-receiving portion 4 and transferred in the vertical direction through the vertical transfer channel 5 toward the horizontal transfer channel. The signal charge transferred to the horizontal transfer channel is further transferred in the horizontal direction through the horizontal transfer channel, and then amplified by an amplifier, which is connected to one end of the horizontal transfer channel, and then outputted, as in the case of the image sensor shown in FIG. 9.

In the two-dimensional image sensor, as shown in FIG. 1, the width W1 of the second portion 5b located beside the pixel isolation region 7 of the vertical transfer channel 5 is wider than the width W0 of the first portion 5a of the vertical transfer channel 5 located beside the light-receiving portion 4. When the width of the vertical transfer channel 5 is at least partially widened like this, the width of the vertical transfer channel 5 is virtually widened, and the amount of charge that the vertical transfer channel 5 can transfer is increased. In addition, the second portion 5b of the increased width of the vertical transfer channel 5 is the portion located beside the pixel isolation region 7, and this therefore exerts no influence on the areas of the light-receiving portion 4 and the transfer gate region 6. Therefore, the amount of charge that the vertical transfer channel 5 can transfer can be increased without narrowing the light-receiving portion 4 or the transfer gate region 6.

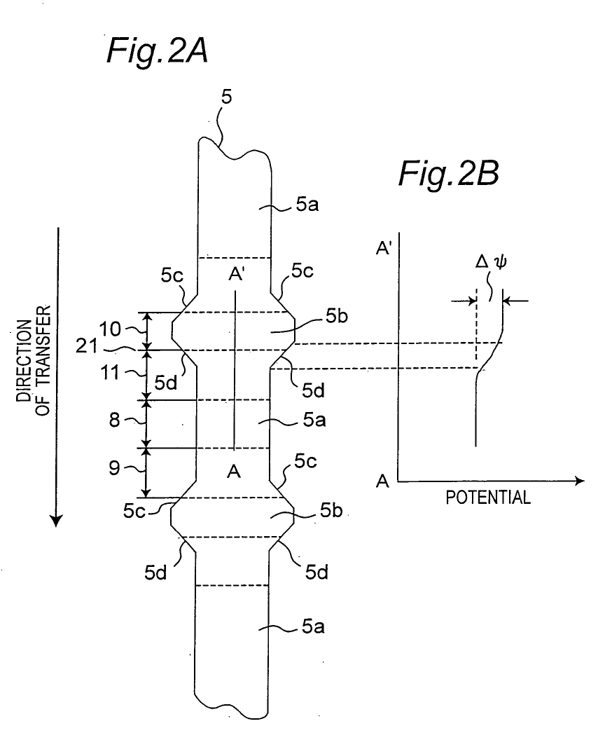

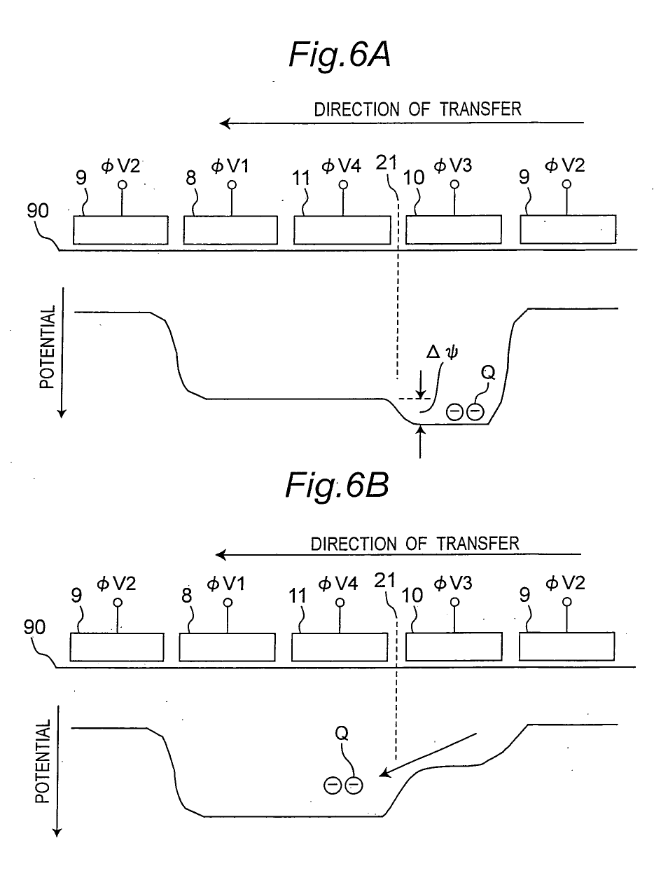

Moreover, when the width W1 of the second portion 5b of the vertical transfer channel 5 is expanded, a potential barrier Δψ against the signal charge may be generated between the second portion 5b of the vertical transfer channel 5 and the first portion 5a adjoining the second portion 5b, as shown in FIG. 2B, due to the widened bottom of the potential. The potential shown in FIG. 2B corresponds to a potential along line A-A′ in FIG. 2A. In the two-dimensional image sensor, as already described, the width of the vertical transfer channel 5 is continuously varied between the second portion 5b (portion corresponding to the vertical transfer electrode 10) and the first portion 5a (portion corresponding to the vertical transfer electrode 11) located adjacent to the second portion 5b on the downstream side in the transfer direction. Therefore, in comparison with the case where the width of the vertical transfer channel 5 is discontinuously (stepwise) varied between the portions 5a and 5b, the potential barrier Δψ against the signal charge transferred from the upstream side to the downstream side in the transfer direction is lowered. In addition, in the two-dimensional image sensor, a boundary 21 between the vertical transfer electrodes 10 and 11 is located on the transition region 5d. Therefore, when the vertical transfer electrodes 10 and 11 are at the same medium-level potential (corresponding to the timing t1 in FIG. 5), a potential barrier Δψ exists between the portions corresponding to the vertical transfer electrodes 10 and 11 of the vertical transfer channel 5, as shown in, for example, FIG. 6A. However, when a voltage applied to the vertical transfer electrode 11 located on the downstream side in the transfer direction is higher than a voltage applied to the vertical transfer electrode 10 located on the upstream side in the transfer direction (corresponding to the timing t2 in FIG. 5), the potential barrier Δφ is canceled, as shown in FIG. 6B. Therefore, the occurrence of vertical transfer failure is suppressed, and signal charge Q is smoothly transferred.

Moreover, as shown in FIG. 1, the length L1 along the transfer direction of the portion 5b of the vertical transfer channel 5 corresponding to the vertical transfer electrode 10 is made shorter than the lengths L0 along the transfer direction of the portions corresponding to each of the vertical transfer electrodes 8, 9 and 11. Therefore, an increase in the occupation area of the portion 5b corresponding to the vertical transfer electrode 10 due to its increased width W1 is suppressed. Conversely, the lengths L0 of the portions corresponding to each of the vertical transfer electrodes 8, 9 and 11 can be increased by that much. Due to the increase in the length L0 of the transfer gate electrode 8 (vertical transfer electrode 8), it is possible to reduce the read voltage at which the signal charge stored in the light-receiving portion is read from the light-receiving portion to the vertical transfer channel. As a result, the storage capacitance of the light-receiving portion 4 can be increased. This is beneficial in securing the amount of signal charge when the cell size is shrunk in accordance with the reduction in size of the solid-state image pickup device and/or the increase in number of pixels of the solid-state image pickup device.

It is desirable to set the sizes W1 and L1 of the portion 5b corresponding to the vertical transfer electrode 10 so that the capacitance of the portion 5b becomes equal to the capacitance of the portion corresponding to the vertical transfer electrode 8. The reason for that is that, when the signal charge is stored in the vertical transfer channel, the storage is achieved in the portions corresponding to at least two vertical transfer electrodes. Therefore, when the storage is achieved in, for example, the portions corresponding to the vertical transfer electrodes 10 and 11 and also in the portions corresponding to the vertical transfer electrodes 11 and 8, the storage is disadvantageously limited by the portion corresponding to either the vertical transfer electrode 8 or 10, whichever has a smaller capacitance.

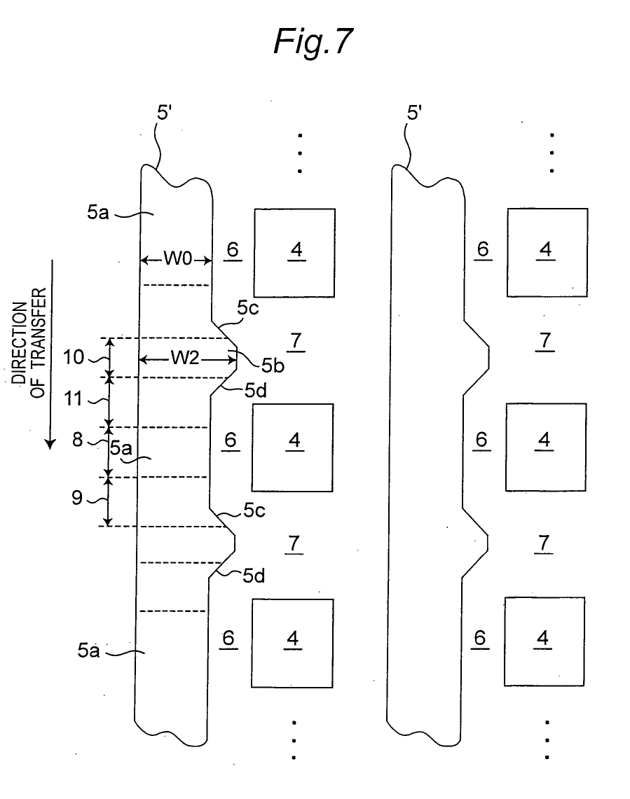

Moreover, although the width W1 of the second portion 5b of the vertical transfer channels 5 located beside the pixel isolation region 7 is made wider with the second portion 5b projecting on both sides in the example of FIG. 1, the present invention is not limited to this. As shown in FIG. 7, the width (indicated by W2) of the second portion 5b of the vertical transfer channel 5 may expand only on one side of the vertical transfer channel 5. Although the width of the second portion 5b of the vertical transfer channel 5′ is expanded only on the right-hand side in the example of FIG. 7, the width may be expanded conversely only on the left-hand side. In either case, the throughput, or the amount of charge that the vertical transfer channel 5 can transfer can be increased without narrowing the light-receiving portion 4 or the transfer gate region 6.

Although the progressive scan type two-dimensional image sensor has been described in the present embodiment, the present invention can also be widely applied to solid-state image pickup devices using other schemes, such as of interlace scan type.

Moreover, although the four-phase drive type has been described in the present embodiment, the present invention can also be applied to a three-phase drive type, six-phase drive type and so on other than the four-phase drive.

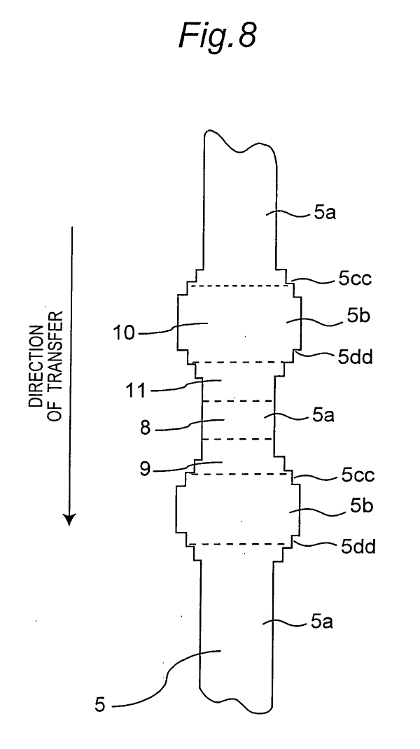

Moreover, in the above described embodiment, the width of the vertical transfer channel 5 is varied continuously between the second portion 5b (portion corresponding to the vertical transfer electrode 10) and the first portions 5a and 5a (portions corresponding to the vertical transfer electrodes 9 and 11) adjoining the second portion 5b on the upstream side and the downstream side in the transfer direction. However, the present invention is not limited to this. As shown in FIG. 8, the width of the vertical transfer channel 5 may be varied stepwise at 5cc and 5dd between the second portion 5b (portion corresponding to the vertical transfer electrode 10) and the first portions 5a and 5a (portions corresponding to the vertical transfer electrodes 9 and 11) located adjacent to the second portion 5b on the upstream side and the downstream side in the transfer direction. In either case, if, of mutually adjoining two vertical transfer electrodes, one vertical transfer electrode located on the downstream side in the transfer direction has a higher applied voltage than the other located on the upstream side in the transfer direction when signal charge passes through the transition region varied continuously or in steps, the possible potential barrier is canceled, and occurrence of vertical transfer failure is suppressed, achieving smooth transfer of the signal charge. Although FIG. 8 shows the vertical transfer channel in which the width of the second portion 5b (portion corresponding to the vertical transfer electrode 10) is widened expanding on both sides with respect to the first portion 5a, the vertical transfer channel 5 may be expanded only on one side as shown in FIG. 7.

Embodiments of the invention being thus described, it will be obvious that the same may be varied in many ways Such variations are not to be regarded as a departure from the spirit and scope of the invention, and all such modifications as would be obvious to one skilled in the art are intended to be included within the scope of the following claims.

1. A solid-state image pickup device comprising:
a plurality of light-receiving portions which are arranged in a matrix form at a surface of a semiconductor substrate and convert incident light into signal charge;
vertical transfer channels each extending in one direction along respective columns of the light-receiving portions on the surface of the semiconductor substrate; and
a set of vertical transfer electrodes which are arranged on each vertical transfer channel and control potentials of corresponding portions of the vertical transfer channel so as to transfer the signal charge through the vertical transfer channel, wherein
the light-receiving portions in each column are separated apart by pixel isolation regions; and
each vertical transfer channel comprises at least a first portion and a second portion, the second portion has a width greater than a width of the first portion, the first portion is aligned with a light-receiving portion in a direction of row, and the second portion is aligned with a pixel isolation region in the direction of row.

2. The solid-state image pickup device as claimed in claim 1, wherein
the vertical transfer channels each have a width varied continuously or stepwise between at least the second portion and the first portion located adjacent to the second portion on a downstream side in a transfer direction; and
a boundary between adjoining two vertical transfer electrodes on each vertical transfer channel exists on a transition region of the vertical transfer channel where the width of the vertical transfer channel is varied between the second portion and the first portion located adjacent to the second portion on the downstream side in the transfer direction.

3. The solid-state image pickup device as claimed in claim 1, wherein
the width of the second portion of the vertical transfer channel is expanded only on one side with respect to the first portion.

4. The solid-state image pickup device as claimed in claim 1, wherein
the second portion faces one vertical transfer electrode;
the first portion faces a plurality of vertical transfer electrodes; and
the second portion has a length shorter than lengths of portions of the first portion that correspond to each of the plurality of vertical transfer electrode.
